(19) United States
(12) Patent Application Publication
(10) Pub. No.: US 2008/0241490 A1
(43) Pub. Date: Oct. 2, 2008

(54) Sprayable Aerogel Insulation

(75) Inventors: Aron Newman, Cambridge, MA (US); Fred Lauten, Andover, MA (US)

Correspondence Address: PROSKAUER ROSE LLP, ONE INTERNATIONAL PLACE, BOSTON, MA, 02110, US

(73) Assignee: Physical Sciences, Inc., Andover, MA (US)

(21) Appl. No.: 12/061,631

(22) Filed: Apr. 2, 2008

Related U.S. Application Data
(60) Provisional application No. 60/909,686, filed on Apr. 2, 2007.

(51) Int. Cl. B32B 5/16; B05D 1/08; B32B 18/00; C23C 16/00

(52) U.S. Cl. 428/206; 427/446; 118/715; 428/325

(57) ABSTRACT

An insulation structure and a method for forming an insulation structure on a surface provide both mechanical integrity and insulative capabilities in applications and environments involving extreme temperatures and compressive forces. The insulation structure includes aerogel agglomerates formed by combining ceramic particles with aerogel particles. The insulation structure may further include ceramic particles. The aerogel agglomerates and ceramic particles are thermally sprayed on a surface to form a graded or layered structure. The method for forming an insulation structure includes spray-drying and post-drying a mixture of ceramic particles, aerogel particles, water, and a binder.

### CROSS-REFERENCE TO RELATED APPLICATION

This application claims the benefit of and priority to U.S. provisional patent application Ser. No. 60/909,686, filed on Apr. 2, 2007 and entitled “Sprayable Aerogel Insulation,” the disclosure of which is hereby incorporated by reference in its entirety.

### GOVERNMENT RIGHTS

This invention was made with government support under Contract No. N00014-05-M-0188, awarded by the United States Navy. The government may have certain rights in the invention.

### FIELD OF THE INVENTION

The invention relates generally to an insulation structure and method of producing an insulation structure on a surface, and more particularly to a mechanically robust insulation structure and method of producing this structure on a surface by thermal spraying agglomerated aerogel particles and fully-dense particles.

### BACKGROUND OF THE INVENTION

Many applications require mechanically robust thermal protection systems to survive extreme environments, including environments that involve extreme temperatures and compressive forces. For example, the Navy develops hypersonic projectiles for shipboard rail guns, and one of the challenges is managing the high heating rate (1000° C./sec) in the high-G environment (40 kG) of the Mach 7 launch. Current technology provides materials with either mechanical strength or insulative abilities, but not both. As a result, two or more different materials, with their added construction costs and weights, are necessary to provide a robust thermal protection system.

### SUMMARY OF THE INVENTION

The invention, in one aspect, features an insulation structure that simultaneously provides mechanical strength and insulation to objects subjected to extreme environmental conditions, including extreme heat and compressive forces. In one embodiment, the insulation structure includes ceramic particles combined with aerogel particles. In another embodiment, the insulation structure includes agglomerate structures made of aerogel particles and ceramic particles. In yet another embodiment, the insulation structure includes a combination of agglomerate structures with ceramic particles.

Embodiments of the invention may employ any type of ceramic and aerogel materials. For example, in one embodiments, the aerogel particles are silica aerogel particles. In some embodiments, the ceramic particles are fully-dense particles. In another embodiment, the ceramic particles are soda-lime glass spheres. In yet another embodiment, the ceramic particles are alumina particles.

In one embodiment, the insulation structure is formed by thermal spraying the ceramic particles and the combination of ceramic particles and aerogel particles.

In some embodiments, the aerogel particles and ceramic particles are arranged in a particular way in the insulation structure. For example, the aerogel particles and ceramic particles form a graded insulation structure in which the ceramic particles are nearer to a surface than the aerogel particles. In other embodiments, the insulation structure is a layered structure. For example, the insulation structure may include a first layer of ceramic particles, a second layer of ceramic particles blended with the combination of ceramic particles and aerogel particles, and a third layer of a combination of ceramic particles and aerogel particles.

In some embodiments, the proportions of ceramic materials, aerogel particles, and agglomerated structures are controlled to provide desired thermal and mechanical properties for the insulation structure. In some embodiments, the insulation structure is 10-30% ceramic particles and 70-90% agglomerate structures. In other embodiments, the ratio of ceramic particles to aerogel particles ranges from 1:1 to 1:10 by weight.

In another aspect of the invention, a method of forming an insulation structure on a surface is provided. In one embodiment the method includes combining aerogel particles and ceramic particles into agglomerate structures and thermal spraying the agglomerate structures on a surface. In another embodiment, thermal spraying includes thermal spraying the agglomerate structures and ceramic particles.

Embodiments of the invention may employ a variety of thermal spraying technologies and methods. Example thermal spraying technologies include plasma spraying and high velocity oxy-fuel spraying. Example methods for thermal spraying include plasma spraying at a distance of 5-50 centimeters from a surface or thermal spraying includes plasma spraying using 200-500 amperes of current.

In another embodiment, the method includes thermal spraying layers of agglomerate structures and ceramic particles. For example, the method may include thermal spraying a first layer of the ceramic particles, thermal spraying a second layer of ceramic particles blended with the agglomerate structures; and thermal spraying a third layer of the agglomerate structures.

In one embodiment, agglomerate structures are formed by mixing aerogel particles, the ceramic particles, water, and a binder, and drying the resulting mixture. Drying the resulting mixture may include spray-drying the mixture.

In some embodiments, the process of forming an insulation structure on a surface includes mixing aerogel particles, ceramic particles, water, and a binder to form a mixture, spray-drying the mixture, post-drying the spray-dried mixture to form an agglomerate powder, thermal spraying the post-dried agglomerate powder and ceramic particles on a surface to form a porous structure thereon, sealing the surface of the porous structure with a polymer barrier, and applying a carbon fabric or epoxy layer to the surface of the polymer barrier.

In another aspect, the invention relates to an apparatus for forming an insulation structure on a surface. In some embodiments, the apparatus includes a mixer to mix aerogel particles and ceramic particles and a spray gun for spray-drying the resulting mixture. The apparatus may further include a plasma sprayer device, which heats and sprays ceramic particles and the spray-dried mixture on a surface.

The details of one or more examples are set forth in the accompanying drawings and description. Further features, aspects, and advantages of the invention will become apparent from the description, the drawings, and the claims.

### BRIEF DESCRIPTION OF THE DRAWINGS

The foregoing and other objects, feature and advantages of the invention, as well as the invention itself, will be more fully understood from the following illustrative description, when read together with the accompanying drawings which are not necessarily to scale.

FIG. 1A is a photograph of a portion of a missile body having an exterior surface covered by an insulation structure, according to an illustrative embodiment of the invention.

FIG. 1B is a cross-sectional view of the portion of the missile body of FIG. 1A.

FIG. 2A is an electron micrograph of silica aerogel particles employed in one embodiment of the invention.

FIG. 2B is an electron micrograph of soda-lime glass particles employed in one embodiment of the invention.

FIG. 2C is an electron micrograph of agglomerate particles formed by spray-drying a mixture of the particles of FIGS. 2A and 2B according to one embodiment of the invention.

FIG. 3 is an electron micrograph of a cross-section of agglomerate particles thermally sprayed on carbon steel.

FIG. 4 is a flow diagram of a process for forming an insulation structure on a surface according to one embodiment of the invention.

FIG. 5 is a block diagram illustrating a process for forming an insulation structure on a surface according to another embodiment of the invention.

FIG. 6 is a block diagram of a system for forming aerogel agglomerates according to an embodiment of the invention.

FIG. 7 is a block diagram of a system for thermal spraying an insulation structure on a surface according to an embodiment of the invention.

FIG. 8 is a flow diagram of a process for forming an insulation structure on a surface according to another embodiment of the invention.

FIG. 9 is a flow diagram of a process for forming an insulation structure on a surface according to another embodiment of the invention.

FIG. 10 is a graph showing thermal conductivity measurements of a thermally sprayed insulation structure according to one embodiment of the invention.

FIG. 11 is a graph showing compressive strength measurements of thermally sprayed insulation structures according to one embodiment of the invention.

FIG. 12 is a graph showing computer simulated temperature versus time profiles for the layers of an insulation structure on a projectile after being launched, according to one embodiment of the invention.

### DESCRIPTION OF THE INVENTION

Plasma spraying an aerogel structure on a surface of a given object is a low-cost and scalable way of insulating that object. However, the problem with plasma spraying aerogel particles is that their low density prevents them from being introduced into a plasma. The second problem is bonding the aerogel particles to a surface. Typically, plasma spray powders melt in the plasma and rapidly solidify on the thermally sprayed surface. Either sintering or melting of the aerogel particles is undesirable because the aerogel will lose its insulative ability. An aspect of the invention addresses these problems by providing a method of forming an insulation structure on a surface that involves thermal spraying an agglomeration of the aerogel particles with fully dense particles, such as soda-lime glass particles. The lower melting of soda-lime glass particles softens and provides the adhesive capability to build a mechanically robust insulating structure. Also, spray technology allows for deposition on flat and irregular shaped surfaces and thereby decreases construction costs.

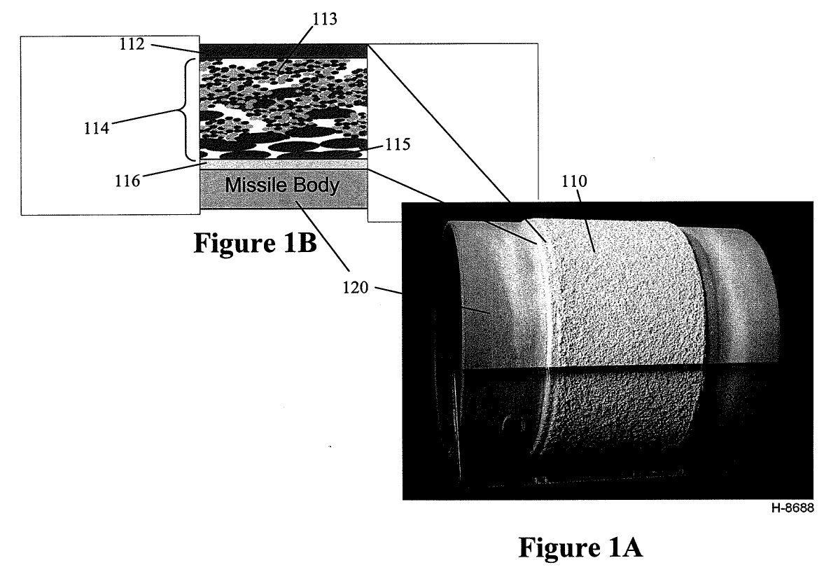

FIG. 1A shows a portion of the steel tubing of a missile body 120 having an exterior surface covered by a thermally sprayed insulation structure 110 according to an embodiment of the invention. In this embodiment, the insulation structure 110 is a 2 mm thick thermally sprayed graded insulation structure. As shown in FIG. 1B, in one embodiment, a bond coat 116 may attach to the surface of the missile body 120. The bond coat manages the Coefficient of Thermal Expansion (CTE) mismatch between the insulation structure 110 and the missile body 120. For example, a bond coat of NiCrAlY or other nickel aluminides may be used to decrease the CTE difference between silica aerogel of the insulation structure 110 and the steel substrate of the missile body 120. In other embodiments, a bond coat is not used.

In the embodiment shown in FIG. 1B, the insulation structure 110 includes agglomerate structures 113 and ceramic particles 115 arranged in a graded sprayed aerogel oxide structure 114. This graded oxide structure 114 provides mechanical integrity and insulation to the missile body in extreme environments. In this embodiment, an appropriate top coat 112 is applied over the graded oxide structure 114 to provide protection from shear stresses.

The ceramic particles provide the mechanical integrity and the aerogel particles provide the insulative ability of the graded insulation structure. The ceramic particles may function as an adhesive for binding the aerogel particles to a given surface. In some embodiments, the insulation structure is graded so that the insulation nearer to the given surface contains more ceramic particles for mechanical support. Examples of aerogel particles include silicon oxides, aluminum oxides, or zirconium oxides. Examples of ceramic particles include fully-dense refractory particles, borosilicate glass, soda lime glass, metals with high melting points, such as tungsten, or refractory oxides, which are robust to oxide environments. In some embodiments, metal or polymer particles may be used in place of ceramic particles. For example, an agglomerate may include fully dense metal particles and aerogel particles.

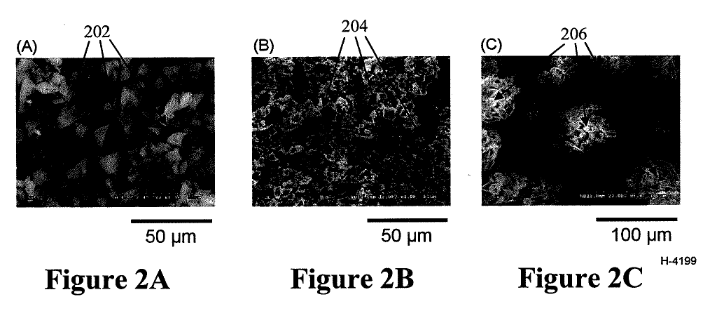

FIGS. 2A-2C show examples of aerogel particles, ceramic particles, and agglomerates incorporated into an embodiment of the insulation structure. FIG. 2A shows silica aerogel particles 202, FIG. 2B shows soda-lime glass particles 204, and FIG. 2C shows agglomerates 206 formed by spray-drying the silica aerogel particles 202 and the soda-lime glass particles 204. The spherical nature of the agglomerates 206 improves the ability of an agglomerate powder to flow, for example, to facilitate a consistent input of agglomerate powder into a plasma via a powder feeder.

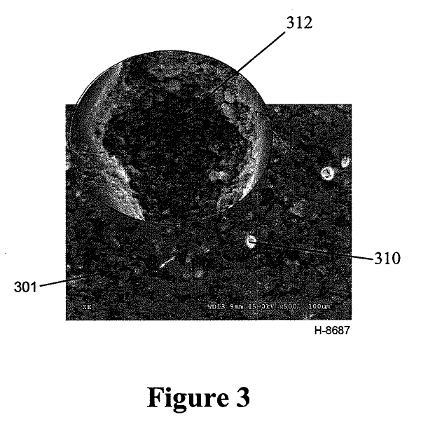

FIG. 3 shows a sample of thermally sprayed agglomerates 301 according to one embodiment. The sample was thermally sprayed on carbon steel, mounted in epoxy, and polished. The darker regions filled with epoxy indicate the size and distribution of the pores within the sample. FIG. 3 also shows an expanded cross-sectional view of a single thermally sprayed agglomerate particle 310. As shown, the agglomerate particle 310 is hollow 312, which is typical for spray-dried particles. As further shown in FIG. 3, the small particles making up the agglomerate particle 310 have not sintered during the thermal spraying process. Moreover, the small particles making up the agglomerate particle 310 are the same size as the original particles that were combined together to make the agglomerate particles. Therefore, the insulation structure according to this embodiment not only includes the large hollow pores 312, but also the smaller pores within the aerogel particles.

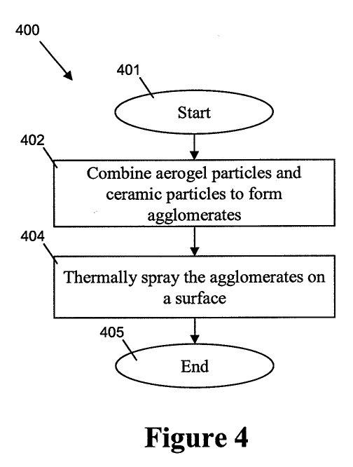

FIG. 4 is a flow diagram of a process 400 for forming an insulation structure on a surface according to one embodiment of the invention. After the process 400 starts 401, ceramic particles are combined with aerogel particles to form agglomerates 402. Next, the agglomerates are thermally sprayed 404 on a given surface. Then, the process 400 ends.

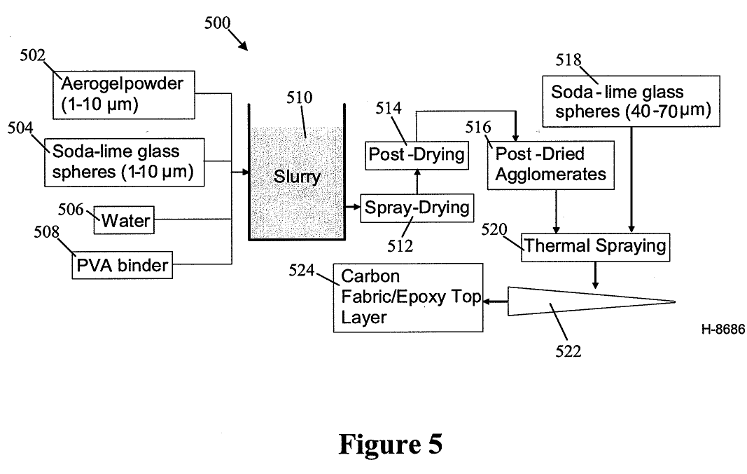

FIG. 5 shows a block diagram of a process 500 for forming an insulation structure according to one embodiment. In some embodiments, the aerogel particles or powder is made by removing the solvent from sol-gel solution. Typically, this is performed by supercritical drying, in which a solvent is extracted from an aerogel solution by carefully controlling temperature and pressure to maintain the porous structure of the aerogel. Cabot Corp. has developed a bench top supercritical drying process for general purpose locations that can be performed at ambient pressure. In one example method, aerogel powder 502, soda-lime glass spheres 504, water 506, and a binder 508, are mixed into a slurry 510 at ambient temperature and pressure. In some embodiments, the size of the aerogel powder 502 and soda-lime spheres 504 may range between 1 and 10 μm. Also, the binder 508 may include a resin material. In this embodiment, the binder is polyvinyl alcohol (PVA). In some embodiments, the slurry composition 510 may contain 2-10% solid material (i.e., the aerogel particles and ceramic particles).

Next, the example method 500 employs a spray-drying process 510 to transform the slurry 510 into agglomerate powders. The spray-drying process 512 may include spraying the slurry 510 through a nozzle and heating the droplets of slurry as they exit the nozzle into a collection chamber. Because of the porosity of aerogels, the agglomerate powder may require a post-drying process 514 to extract any water particles remaining after the spray-drying process 512. The spray-dried and/or post-dried slurry 510 and a ceramic powder, such as soda-lime glass spheres 518, are then thermally sprayed 520 to produce partially molten powders, which deposit onto a given surface, such as a projectile body. In some embodiments, the method 500 may include feeding a thermal spraying device with varying proportions of the agglomerates and ceramic particles to produce a uniform graded insulation structure on a surface. Lastly, in some embodiments, the porous structure of the thermally sprayed insulation may be sealed, for example, with a thin polymer barrier and laid-up with an outer carbon fabric/epoxy layer 524.

Embodiments of the insulation structure may include different proportions and arrangements of ceramic particles and aerogel particles depending upon the application or intended environment. In some embodiments, the insulation structure is 10-30% ceramic particles and 70-90% agglomerate structures. In other embodiments, the ratio of ceramic particles to aerogel particles ranges from 1:1 to 1:10 by weight.

An insulation structure formed on a surface by thermal spraying aerogel agglomerate particles in a graded structure on that surface provides many significant benefits. Spray deposition processes provide for the easy application of materials to surfaces with irregular shapes with low manufacturing costs. Also, the graded insulation structure provides significant strength to withstand high compressive forces, for example, during high-G launches and supersonic flight of projectiles and missiles. Also, thermally sprayed aerogel agglomerate insulation structures have low thermal conductivity and are light weight.

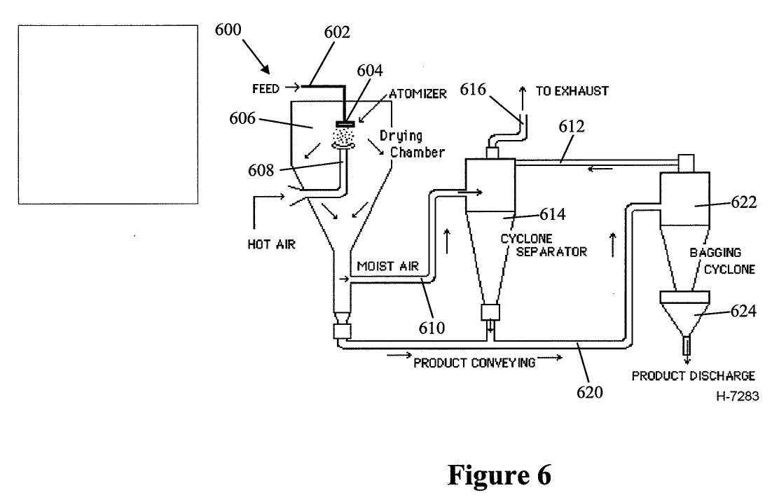

FIG. 6 is a block diagram of a system 600 for forming aerogel agglomerates 600 according to an embodiment of the invention. The system 600 includes a drying chamber 606, a cyclone separator 614, and a bagging cyclone 622. The drying chamber 606 includes an atomizer 604, which is in fluid communication with a atomizer input channel 602. In some embodiments, the atomizer 604 may be replaced with a rotary nozzle. The drying chamber 606 is in fluid communication with: (1) the cyclone separator 614 via channel 610 and channel 620 and (2) the bagging cyclone 622 via channel 620. The bagging cyclone 622 is in fluid communication with the cyclone separator 614 via channels 612 and 620.

A mixture of aerogel particles, ceramic particles, water, and a binder may be fed into the atomizer input channel 602, which carries the mixture to an atomizer 604. The atomizer 604 atomizes and sprays the mixture into a drying chamber 606. Hot air is supplied to the drying chamber through channel 608. The hot air dries the atomized particles in the drying chamber 606 and channel 620 carries the dried particles (e.g., the agglomerates) to the bagging cyclone 622. The bagging cyclone 622 separates the hot air from the dried particles and the channel 612 carries the hot air to the cyclone separator 614. Channel 610 transports hot moist air to the cyclone separator 614, which separates the hot moist air from any particles and channel 616 carries the hot air out of the system. Channel 620 carries dried particles from the cyclone separator 614 to the bagging cyclone 622, which discharges the dried particles from the system 600.

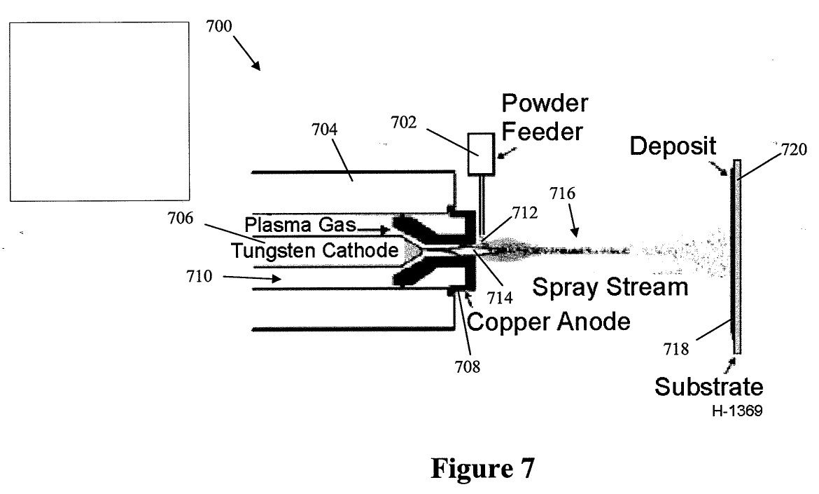

FIG. 7 is a block diagram of a system 700 for thermal spraying an insulation structure on a surface according to an embodiment of the invention. The system 700 includes a feeder 702, a body 704, an electrode 706, a nozzle 708, and a chamber 710. In operation, an electrical current is applied to the electrode 706 and gas is supplied to the chamber 710 to create an plasma arc 714 emanating out of the nozzle 708. The system 700 then adds a mixture of aerogel agglomerates and ceramic particles 712 to the plasma arc 714 through the feeder 702. In this way, the system 700 creates a spray stream 716 which deposits a heated mixture of agglomerates and ceramic particles 712 on the surface of the substrate 720 to form an insulation structure 718. The plasma arc 714 softens the ceramic particles and the ceramic particles in the agglomerates and the ceramic particles adhere to the surface of the substrate 718. In another embodiment, only aerogel agglomerates are fed into the plasma arc 714. In some embodiments, a graded insulation structure is formed by varying the ratio of ceramic particles to aerogel particles introduced into the plasma by the feeder 702.

According to another aspect of the invention, two parameters are controlled to properly synthesize the graded insulation structure on a surface: (1) the stand-off distance between the thermal spraying system and the surface of the substrate, and (2) the electrical current applied to the thermal spraying device. In one embodiment, the stand-off distance may be about 15 cm and the thermal spraying device current may be about 400 amps. In some embodiments, the stand-off distance may range between 5 and 50 cm and the thermal spraying device current may range between 200 and 500 amps. In some embodiments, the invention may employ the use of any number of thermal spraying devices including a high velocity oxy-fuel spraying device or a plasma spraying device that generates a plasma of 30,000 volts between its anode and cathode in Argon gas.

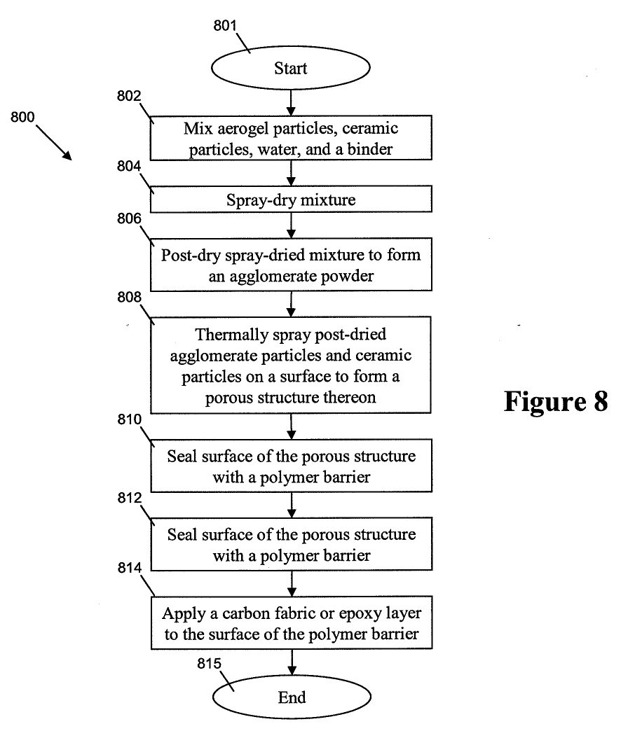

FIG. 8 is a flow diagram of a process 800 for forming an insulation structure on a surface according to one embodiment of the invention. After the process 800 starts 801, aerogel particles, ceramic particles, water, and a binder are combined mixed together 802. Next, the mixture is spray-dried 804 and the spray-dried mixture, in turn, is post-dried 806 to form agglomerate particles. Next, the post-dried agglomerate particles are thermally sprayed 808 on a given surface to form a porous structure thereon. The surface of the porous structure is then sealed 810 with a polymer barrier. Before the process 800 ends 815, a carbon fabric or epoxy layer is applied 814 to the surface of the polymer barrier.

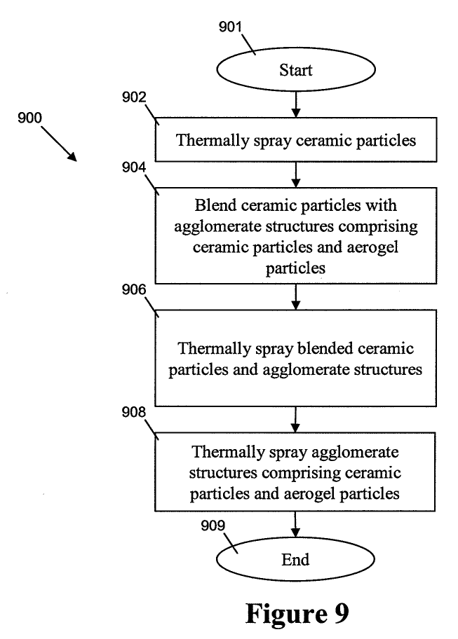

FIG. 9 is a flow diagram of a process 900 for forming a layered insulation structure on a surface according to one embodiment of the invention. After the process 900 starts 901, ceramic particles are thermally sprayed 902 on a given surface. Next, ceramic particles are blended with agglomerate structures that include ceramic particles and aerogel particles 904. Next, the blended ceramic particles and agglomerate structures are thermally sprayed 906 to form a second layer on the surface of the thermally sprayed ceramic particle layer. Before the process 900 ends 909, agglomerate structures that include ceramic particles and aerogel particles are thermally sprayed 908 on the surface of the thermally sprayed blend of ceramic particles and agglomerate structures. In other embodiments, the process for forming a layered insulation structure may include forming two or more layers, each with different particles or combinations of particles.

Tests and measurements were performed on the following three thermally sprayed samples:

1. 100% Spheriglass® 3000 (borosilicate glass)

2. 80% Spray-dry (agglomerate particles), 20% Spheriglass® 3000

3. 100% Spray-dry (agglomerate particles)

The following table summarizes various properties of the samples:

| | Density | Diffusivity | k | Cp | Porosity |
|---|---|---|---|---|---|
| Sample | (ρ, g/cm³) | (α, cm²/sec) | (W/m K) | (cal/g C.) | (%) |
| 1 | 1.479 | 6.96E−03 | 0.76 | 0.740 | 41% |
| 2 | 1.276 | 4.74E−03 | 0.41 | 0.670 | 45% |
| 3 | 1.144 | 2.66E−03 | 0.18 | 0.600 | 48% |

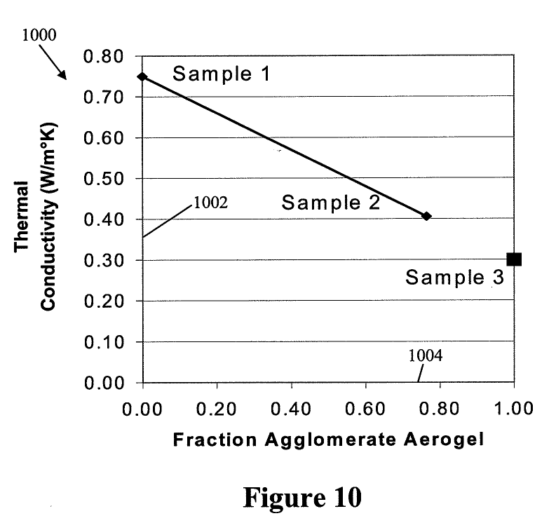

The thermal conductivity of samples 1 and 2 were determined by measuring their porosity and calculating their densities. By linearly extrapolating heat capacity and thermal diffusivity values from samples 1 and 2, the thermal conductivity of sample 3 was determined based on the expression k=α cₚ ρ, where k is the thermal conductivity (W/mK), α is the thermal diffusivity (cm²/s), cₚ is the heat capacity (J/g° K), and ρ is the density. This method yielded a thermal conductivity of 0.18 W/m° K for sample 3. FIG. 10 is a graph 1000 showing the thermal conductivity 1002 versus the fraction of aerogel agglomerates 1004 in the three samples.

The porosities of the samples were measured by performing an image analysis technique. The image analysis technique involved taking a backscatter image of 10 regions of the samples' surface at 1000× magnification. According to this method it was determined that sample 3 has 48% porosity +/−8%.

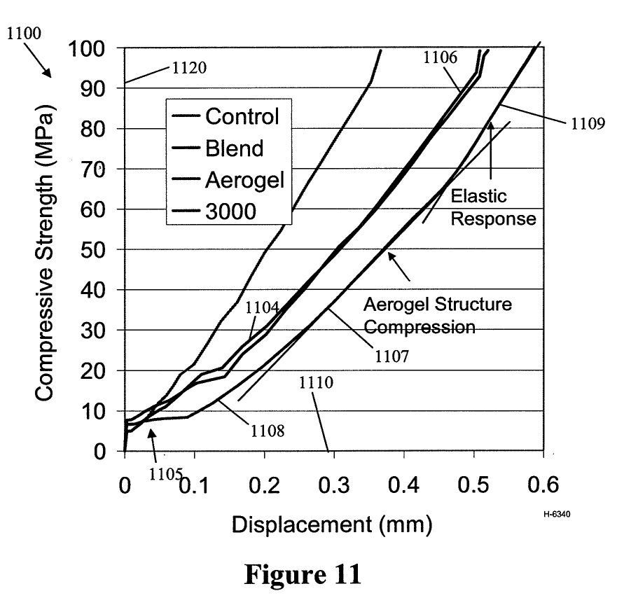

FIG. 11 is a graph 1100 showing the compressive strength (1120) of the three thermally sprayed samples based on loading a 2.5 mm diameter flat pin onto the samples' surfaces at a constant displacement rate 1110. The compressive strength tests were stopped at the limit of the 500 N load cell. Curve 1104 represents the measurements for sample 2, curve 1106 represents the measurements for sample 1, and curve 1108 represents the measurements for sample 3. The region 1105 at low displacement distances' is the result of the uneven topography of the samples' surfaces. Small particles contained on the samples' surfaces were crushed into the insulation structure. The first linear region 1107 (between about 0.25 mm and 0.45 mm of displacement) is attributed to the collapse of the aerogel structures and the second linear region 1109 is attributed to the elastic response of the test fixture and the crushed glass. The compressive strength of sample 3 was taken to be 20 MPa because damage to the agglomerate aerogel structures only begins at compressive pressures greater than 20 MPa.

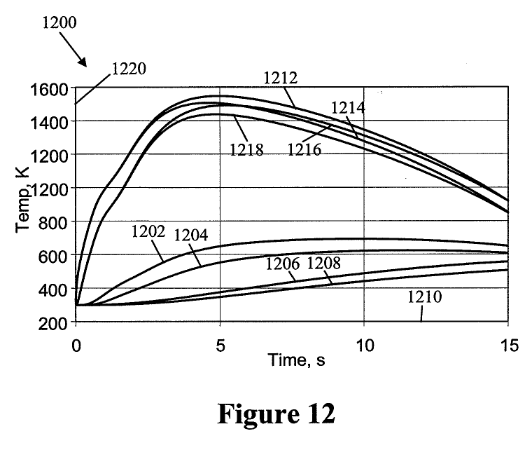

FIG. 12 is a graph showing the computer simulated temperature (° K) 1220 versus time (seconds) 1210 profiles for the layers of an embodiment of the insulation structure on the surface of a projectile after being launched. Curve 1202 represents the temperature profile for a thermally sprayed aerogel insulation structure layer with a thickness of 1500 μm. Curve 1204 represents the temperature profile for a thermally sprayed aerogel insulation structure layer with a thickness of 2000 μm. Curve 1206 represents the temperature profile for the steel body of the projectile using a thermally sprayed aerogel insulation structure layer with a thickness of 1500 μm. Curve 1206 represents the temperature profile for the steel body of the projectile using a thermally sprayed aerogel insulation structure layer with a thickness of 1500 μm. Curve 1208 represents the temperature profile for the steel body of the projectile using a thermally sprayed aerogel insulation structure layer with a thickness of 2000 μm. Curve 1216 represents the temperature profile for a carbon/phenolic top layer using a thermally sprayed aerogel insulation structure layer with a thickness of 2000 μm. Curve 1218 represents the temperature profile for the carbon/phenolic top layer using a thermally sprayed aerogel insulation structure layer with a thickness of 1500 μm. Curve 1214 represents the temperature profile for the outside surface of the carbon/phenolic top layer using a thermally sprayed aerogel insulation structure layer with a thickness of 1500 μm. Curve 1212 represents the temperature profile for the outside surface of the carbon/phenolic top layer using a thermally sprayed aerogel insulation structure layer with a thickness of 2000 μm. According to these calculations, the surface temperature of the exterior surface decreases by about 100° C. when the thickness of the aerogel insulation layer is increased by 33%.

The insulation structure according to embodiments of the invention may by used for a variety of applications. Computer modeling results demonstrate that an insulation structure according to one embodiment can moderate the internal temperature of a projectile, such as a missile. For example, an insulation structure thickness of less than 3.75 mm will produce an internal wall temperature less than 150° C. In one embodiment, the insulation structure is applied to hypersonic projectiles. In another embodiment, the insulation structure is applied to steam pipes to provide insulation and mechanical robustness.

While the invention has been particularly shown and described with reference to specific embodiments, it should be understood by those skilled in the art that various changes in form and detail may be made therein without departing from the spirit and scope of the invention as defined by the appended claims.

What is claimed:

1. An insulation structure comprising:
ceramic particles combined with aerogel particles.

2. The insulation structure of claim 1, wherein the combination of the aerogel particles and ceramic particles form agglomerate structures.

3. The insulation structure of claim 2, further comprising ceramic particles.

4. The insulation structure of claim 3, wherein the ceramic particles are refractory particles.

5. The insulation structure of claim 3, wherein the aerogel particles and ceramic particles form a graded structure.

6. The insulation structure of claim 5, wherein the ceramic particles are nearer to a surface than the aerogel particles.

7. The insulation structure of claim 5, wherein the insulation structure comprises:
a first layer of ceramic particles;
a second layer of ceramic particles blended with the combination of ceramic particles and aerogel particles; and
a third layer of a combination of ceramic particles and aerogel particles.

8. The insulation structure of claim 3, wherein the insulation structure is formed by thermal spraying the ceramic particles and the combination of ceramic particles and aerogel particles.

9. The insulation structure of claim 1, wherein the ceramic particles are fully-dense refractory particles.

10. The insulation structure of claim 5, wherein the insulation structure is 10-30% ceramic particles and 70-90% agglomerate structures.

11. The insulation structure of claim 1, wherein the ratio of ceramic particles to aerogel particles ranges from 1:1 to 1:10 by weight.

12. The insulation structure of claim 1, wherein the aerogel particles are silica aerogel particles.

13. The insulation structure of claim 1, wherein the ceramic particles are soda-lime glass spheres.

14. The insulation structure of claim 1, wherein the ceramic particles are alumina.

15. A method of forming an insulation structure on a surface, comprising:
combining aerogel particles and ceramic particles to form agglomerate structures; and
thermal spraying the agglomerate structures on a surface to form an insulation structure thereon.

16. The method of claim 15, wherein thermal spraying includes thermal spraying the agglomerate structures and ceramic particles.

17. The method of claim 15, wherein thermal spraying includes plasma spraying.

18. The method of claim 15, wherein thermal spraying includes high velocity oxy-fuel spraying.

19. The method of claim 15, wherein thermal spraying includes thermal spraying a layered structure of agglomerate structures and ceramic particles.

20. The method of claim 19, wherein thermal spraying a layered structure comprises:
thermal spraying a first layer of the ceramic particles;
thermal spraying a second layer of ceramic particles blended with the agglomerate structures; and
thermal spraying a third layer of the agglomerate structures.

21. The method of claim 17, wherein thermal spraying includes plasma spraying at a distance of 5-50 centimeters from the surface.

22. The method of claim 17, wherein thermal spraying includes plasma spraying using 200-500 amperes of current.

23. The method of claim 15, wherein combining aerogel particles and ceramic particles comprises:
mixing the aerogel particles, the ceramic particles, water, and a binder to form a mixture; and
drying the mixture to form agglomerate structures.

24. The method of claim 21, wherein drying the mixture includes spray-drying the mixture.

25. A method of forming an insulation structure on a surface, comprising:
mixing aerogel particles, ceramic particles, water, and a binder to form a mixture;
spray-drying the mixture;
post-drying the spray-dried mixture to form an agglomerate powder;
thermal spraying the post-dried agglomerate powder and ceramic particles on a surface to form a porous structure thereon;
sealing the surface of the porous structure with a polymer barrier; and
applying a carbon fabric or epoxy layer to the surface of the polymer barrier.

26. An apparatus for forming an insulation structure on a surface, comprising:
means for thermal spraying ceramic particles and agglomerates made of ceramic particles and aerogel particles on a surface.
